(19) United States
(12) Patent Application Publication
(10) Pub. No.: US 2011/0254054 A1
(43) Pub. Date: Oct. 20, 2011

(54) SEMICONDUCTOR DEVICE

(75) Inventor: Satoru ITOU, Hyogo (JP)

(73) Assignee: PANASONIC CORPORATION, Osaka (JP)

(21) Appl. No.: 13/172,115

(22) Filed: Jun. 29, 2011

Related U.S. Application Data
(63) Continuation of application No. PCT/JP2009/005949, filed on Nov. 9, 2009.

(30) Foreign Application Priority Data
Jan. 8, 2009 (JP) 2009-002786

(51) Int. Cl. H01L 29/12

(52) U.S. Cl. 257/192; 257/369; 257/E29.068

(57) ABSTRACT

A semiconductor device has at least an n-type MIS transistor, which includes a first gate insulating film formed on a first semiconductor region in a semiconductor substrate, a first gate electrode formed on the first gate insulating film, first sidewalls formed on the side surfaces of the first gate electrode, and carbon-containing silicon regions formed laterally outside the first sidewalls. The top surfaces of the carbon-containing silicon regions are at a level higher than the top surface of a region in the first semiconductor region lying under the first gate insulating film.

### CROSS-REFERENCE TO RELATED APPLICATION

This is a continuation of PCT International Application PCT/JP2009/005949 filed on Nov. 9, 2009, which claims priority to Japanese Patent Application No. 2009-002786 filed on Jan. 8, 2009. The disclosures of these applications including the specifications, the drawings, and the claims are hereby incorporated by reference in their entirety.

### BACKGROUND

The present disclosure relates to a semiconductor device and a method for manufacturing the same, and more particularly, to a semiconductor device including a metal insulator semiconductor field effect transistor (MISFET) having a silicon region containing carbon, etc, and a method for manufacturing the same.

In recent years, in order to improve the drive capability of MISFETs (hereinafter referred to as “MIS transistors”), an attempt has been made to increase the carrier mobility by applying a stress to the channel region. As a technique of applying a stress to the channel region, a carbon-containing silicon region may be provided in the source/drain regions of an n-type MIS transistor.

A method for manufacturing a conventional semiconductor device will be described hereinafter with reference to FIGS. 7A-7C (see Y. Liu et. al., “Strained Si Channel MOSFETs with Embedded Silicon Carbon Formed by Solid Phase Epitaxy,” 2007 Symposium on VLSI Technology Digest of Technical Papers, pp. 44-45, for example). FIGS. 7A-7C are cross-sectional views illustrating main steps of the method for manufacturing the conventional semiconductor device in the order in which the semiconductor device is manufactured.

Initially, as shown in FIG. 7A, an isolation region 101 is formed in an upper portion of a semiconductor substrate 100 made of silicon. As a result, a semiconductor region 100a surrounded by the isolation region 101 is formed in the semiconductor substrate 100. A p-type well region 102 is then formed in the semiconductor substrate 100.

Thereafter, a gate insulating film 103, a gate electrode 104, and a cap film 105 are sequentially formed on the semiconductor region 100a. N-type extension doped regions 106 are then formed in the semiconductor region 100a to lie on opposite sides of the gate electrode 104. A sidewall 108A including an inner sidewall 107 and an outer sidewall 108 is then formed on each of the side surfaces of the gate electrode 104.

As shown in FIG. 7B, n-type impurity ions are implanted into the semiconductor region 100a using the sidewalls 108A as a mask, to form n-type source/drain doped regions 109 in the semiconductor region 100a to lie laterally outside the sidewalls 108A.

Thereafter, carbon ions are implanted into the semiconductor region 100a using the sidewalls 108A as a mask, to form carbon ion-doped regions 110 in the semiconductor region 100a to lie laterally outside the sidewalls 108A.

As shown in FIG. 7C, by thermal treatment, the n-type impurity contained in the n-type extension doped regions 106 is activated to form n-type extension regions 111, while the n-type impurity contained in the n-type source/drain doped regions 109 is activated to form n-type source/drain regions 112. Meanwhile, the carbon ion-doped regions 110 are crystallized to form carbon-containing silicon regions 113.

Thereafter, although not shown, the cap film 105 is removed to expose the top surface of the gate electrode 104. Silicide layers are then formed on the carbon-containing silicon regions 113, and also a silicide layer is formed on the gate electrode 104. Thereafter, an interlayer insulating film, contacts, interconnects, etc. are formed.

Thus, the conventional semiconductor device is manufactured.

In general, when a carbon-containing silicon region has a carbon concentration of 1%, the lattice constant thereof is reduced by about 0.4% compared to the lattice constant of the semiconductor substrate. Therefore, conventionally, the carbon-containing silicon regions 113 can apply a tensile stress to the channel region in the semiconductor region 100a in the gate length direction. This can increase the carrier mobility and thus improve the drive capability of the n-type MIS transistor.

### SUMMARY

However, the conventional semiconductor device has the following problem.

FIG. 8 is a graph showing the relationship between the depth of the carbon-containing silicon region and the magnitude of the tensile stress applied to the channel region in the gate length direction in the conventional semiconductor device. Referring to FIG. 8, this relationship will be described as follows.

The x-axis in FIG. 8 represents the depth of the carbon-containing silicon region. The “depth of the carbon-containing silicon region” as used herein refers to the depth from the top surface of a region in the semiconductor region 100a lying under the gate insulating film 103 to the deepest position of the bottom surfaces of the carbon-containing silicon regions 113 (D in FIG. 7C, for example), as measured when the depth of the top surface of the region in the semiconductor region 100a lying under the gate insulating film 103 is assumed as the reference depth (i.e., 0 nm).

The y-axis in FIG. 8 represents the magnitude of the tensile stress applied to the channel region in the gate length direction by the carbon-containing silicon regions 113 having a depth of X (X=5, 10, 20, 30, 40, 50, and 60) nm.

As shown in FIG. 8, the magnitude of the tensile stress increases with increase in the depth of the carbon-containing silicon region at a comparatively large rate in a range where the depth X of the carbon-containing silicon region is comparatively small. In a range where the depth X is comparatively large, the magnitude of the tensile stress increases with increase in the depth of the carbon-containing silicon region at a comparatively small rate. This is considered because, when the depth X of the carbon-containing silicon region exceeds a predetermined depth (specifically, X=50 nm, for example), the bottom surface of the carbon-containing silicon region becomes away from the region where carriers move (i.e., the channel region), failing in effective application of the tensile stress by the carbon-containing silicon region to the channel region in the gate length direction.

Thus, the magnitude of the tensile stress does not increase with increase in the depth of the carbon-containing silicon region at a fixed rate, but the rate at which the magnitude of the tensile stress increases decreases with increase in the depth of the carbon-containing silicon region.

For the reason described above, merely increasing the depth of the carbon-containing silicon region beyond the predetermined depth will not succeed in increasing the magnitude of the tensile stress applied to the channel region in the gate length direction at a large rate, and thus will not succeed in effectively improving the drive capability of the n-type MIS transistor.

In view of the above, it is an objective of the present disclosure to provide a semiconductor device including an n-type MIS transistor having a carbon-containing silicon region, in which the magnitude of the tensile stress applied to the channel region in the gate length direction is effectively increased.

To achieve the above objective, the semiconductor device in one aspect of the present disclosure is a semiconductor device having at least an n-type MIS transistor, wherein the n-type MIS transistor includes a first gate insulating film formed on a first semiconductor region in a semiconductor substrate, a first gate electrode formed on the first gate insulating film, first sidewalls formed on side surfaces of the first gate electrode, and carbon-containing silicon regions formed laterally outside the first sidewalls, wherein the top surfaces of the carbon-containing silicon regions are at a level higher than the top surface of a region in the first semiconductor region lying under the first gate insulating film.

In the semiconductor device described above, the top surfaces of the carbon-containing silicon regions are at a level higher than the top surface of a region in the first semiconductor region lying under the first gate insulating film, and each of the carbon-containing silicon regions has a thickened portion protruding from the level of the top surface of the region in the first semiconductor region lying under the first gate insulating film. With such thickened portions, by which a tensile stress can be effectively applied to the channel region in the first semiconductor region in the gate length direction, the magnitude of the tensile stress applied to the channel region in the first semiconductor region in the gate length direction can be effectively increased, permitting effective improvement in the drive capability of the n-type MIS transistor.

In the semiconductor device in the aspect of the present disclosure, preferably, the carbon-containing silicon regions are formed in the first semiconductor region and in first silicon layers formed on the first semiconductor region.

In the semiconductor device in the aspect of the present disclosure, preferably, n-type impurity-diffused regions are formed in the carbon-containing silicon regions.

In the semiconductor device in the aspect of the present disclosure, preferably, each of the first sidewalls includes a first inner sidewall having an L-shaped cross-section formed on a side surface of the first gate electrode and a first outer sidewall formed on the first inner sidewall.

Preferably, the semiconductor device in the aspect of the present disclosure further includes a stress insulating film formed above the first semiconductor region, configured to cause a tensile stress in a channel region in the first semiconductor region in a gate length direction, wherein each of the first sidewalls includes a first inner sidewall having an L-shaped cross-section formed on a side surface of the first gate electrode, and the stress insulating film is formed in contact with the first inner sidewall.

With the stress insulating film, by which a tensile stress can be applied to the channel region in the first semiconductor region in the gate length direction, the drive capability of the n-type MIS transistor can be further improved.

Also, with the stress insulating film, which is formed in contact with the first inner sidewalls, not via the first outer sidewalls, and thus can be made close to the channel region in the first semiconductor region by the thickness of the first outer sidewall removed, the tensile stress by the stress insulating film can be effectively applied to the channel region in the semiconductor region in the gate length direction.

Moreover, the stress insulating film, formed in contact with the first inner sidewalls, not via the first outer sidewalls, can be made thin by the thickness of the first outer sidewall removed. Thus, the tensile stress by the stress insulating film can be effectively applied to the channel region in the first semiconductor region in the gate length direction.

Preferably, the semiconductor device in the aspect of the present disclosure further includes first silicide layers formed on the carbon-containing silicon regions.

In the semiconductor device in the aspect of the present disclosure, preferably, the first gate insulating film includes a first high-k insulating film, and the first gate electrode includes a first metal film formed in contact with the first gate insulating film.

In the semiconductor device in the aspect of the present disclosure, preferably, the carbon concentration of the carbon-containing silicon regions is 0.5% or more.

Preferably, the semiconductor device in the aspect of the present disclosure further includes a p-type MIS transistor, wherein the p-type MIS transistor includes a second gate insulating film formed on a second semiconductor region in the semiconductor substrate, a second gate electrode formed on the second gate insulating film, second sidewalls formed on side surfaces of the second gate electrode, and germanium-containing silicon regions formed laterally outside the second sidewalls.

With the above configuration, since the germanium-containing silicon regions can apply a compressive stress to the channel region in the second semiconductor region in the gate length direction, the drive capability of the p-type MIS transistor can be improved.

Preferably, the semiconductor device in the aspect of the present disclosure further includes second silicon layers formed on the germanium-containing silicon regions and second silicide layers formed on the second silicon layers, wherein at least upper portions of the second silicon layers are smaller in germanium concentration than the germanium-containing silicon regions.

In the semiconductor device in the aspect of the present disclosure, preferably, the top surfaces of the germanium-containing silicon regions are at a level higher than the top surface of a region in the second semiconductor region lying under the second gate insulating film.

With the above configuration, the top surfaces of the germanium-containing silicon regions are at a level higher than the top surface of a region in the second semiconductor region lying under the second gate insulating film, and each of the germanium-containing silicon regions has a thickened portion protruding from the level of the top surface of the region in the second semiconductor region lying under the second gate insulating film. With such thickened portions, by which a compressive stress can be effectively applied to the channel region in the second semiconductor region in the gate length direction, the magnitude of the compressive stress applied to the channel region in the second semiconductor region in the gate length direction can be increased effectively, permitting effective improvement in the drive capability of the p-type MIS transistor.

In the semiconductor device in the aspect of the present disclosure, preferably, p-type impurity-diffused regions are formed in the germanium-containing silicon regions.

In the semiconductor device in the aspect of the present disclosure, preferably, the second gate insulating film includes a second high-k insulating film, and the second gate electrode includes a second metal film formed in contact with the second gate insulating film.

In the semiconductor device in the aspect of the present disclosure, preferably, the germanium concentration of the germanium-containing silicon region is 15% or more.

To achieve the above objective, the method for manufacturing a semiconductor device in one aspect of the present disclosure includes the steps of: (a) forming a first gate insulating film on a first semiconductor region in a semiconductor substrate; (b) forming a first gate electrode on the first gate insulating film; (c) forming first sidewalls on side surfaces of the first gate electrode; and (d) forming carbon-containing silicon regions laterally outside the first sidewalls, wherein the top surfaces of the carbon-containing silicon regions are at a level higher than the top surface of a region in the first semiconductor region lying under the first gate insulating film.

In the method described above, the top surfaces of the carbon-containing silicon regions are at a level higher than the top surface of a region in the first semiconductor region lying under the first gate insulating film, and each of the carbon-containing silicon regions has a thickened portion protruding from the level of the top surface of the region in the first semiconductor region lying under the first gate insulating film. With such thickened portions, by which a tensile stress can be effectively applied to the channel region in the first semiconductor region in the gate length direction, the magnitude of the tensile stress applied to the channel region in the first semiconductor region in the gate length direction can be increased effectively, permitting effective improvement in the drive capability of the n-type MIS transistor.

In the method in the aspect of the present disclosure, preferably, the step (d) includes the steps of: (d1) forming first silicon layers on regions in the first semiconductor region lying laterally outside the first sidewalls; (d2) implanting carbon-containing ions into the first silicon layers and regions in the first semiconductor region lying under the first silicon layers, to form carbon ion-doped regions; and (d3) crystallizing the carbon ion-doped regions by thermal treatment, to form the carbon-containing silicon regions.

In the method in the aspect of the present disclosure, preferably, the step (a) includes the step of forming a second gate insulating film on a second semiconductor region in the semiconductor substrate, the step (b) includes the step of forming a second gate electrode on the second gate insulating film, the step (c) includes the step of forming second sidewalls on side surfaces of the second gate electrode, and the step (d) includes the step of (x) forming germanium-containing silicon regions laterally outside the second sidewalls.

By the method described above, since the germanium-containing silicon regions can apply a compressive stress to the channel region in the second semiconductor region in the gate length direction, the drive capability of the p-type MIS transistor having the second gate electrode can be improved.

In the method in the aspect of the present disclosure, preferably, the step (X) includes the steps of: (X1) etching regions in the second semiconductor region located laterally outside the second sidewalls, to form recesses; and (X2) forming the germanium-containing silicon regions in the recesses by epitaxial growth.

In the semiconductor device and the method for manufacturing the same of the present disclosure, the top surfaces of the carbon-containing silicon regions are at a level higher than the top surface of a region in the first semiconductor region lying under the first gate insulating film, and each of the carbon-containing silicon regions has a thickened portion protruding from the level of the top surface of the region in the first semiconductor region lying under the first gate insulating film. With such thickened portions, by which a tensile stress can be effectively applied to the channel region in the first semiconductor region in the gate length direction, the magnitude of the tensile stress applied to the channel region in the first semiconductor region in the gate length direction can be increased effectively, permitting effective improvement in the drive capability of the n-type MIS transistor.

### BRIEF DESCRIPTION OF THE DRAWINGS

FIGS. 1A-1C are cross-sectional views illustrating main steps of a method for manufacturing a semiconductor device of an embodiment of the present disclosure in the order in which the semiconductor device is manufactured.

FIGS. 2A-2C are cross-sectional views illustrating main steps of the method for manufacturing the semiconductor device of the embodiment of the present disclosure in the order in which the semiconductor device is manufactured.

FIGS. 3A-3C are cross-sectional views illustrating main steps of the method for manufacturing the semiconductor device of the embodiment of the present disclosure in the order in which the semiconductor device is manufactured.

FIG. 4 is a graph showing the relationship between the depth of a carbon-containing silicon region and the magnitude of the tensile stress applied to the channel region in the gate length direction in the semiconductor device of the embodiment of the present disclosure and in the conventional semiconductor device.

FIG. 5 is a cross-sectional view illustrating a step of a method for manufacturing a semiconductor device of the first variation of the embodiment of the present disclosure.

FIG. 6 is a cross-sectional view illustrating a configuration of a semiconductor device of the second variation of the embodiment of the present disclosure.

FIGS. 7A-7C are cross-sectional views illustrating main steps of a method for manufacturing a conventional semiconductor device in the order in which the semiconductor device is manufactured.

FIG. 8 is a graph showing the relationship between the depth of a carbon-containing silicon region and the magnitude of the tensile stress applied to the channel region in the gate length direction in the conventional semiconductor device.

### DETAILED DESCRIPTION

An embodiment of the present disclosure will be described hereinafter with reference to the drawings.

### Embodiment

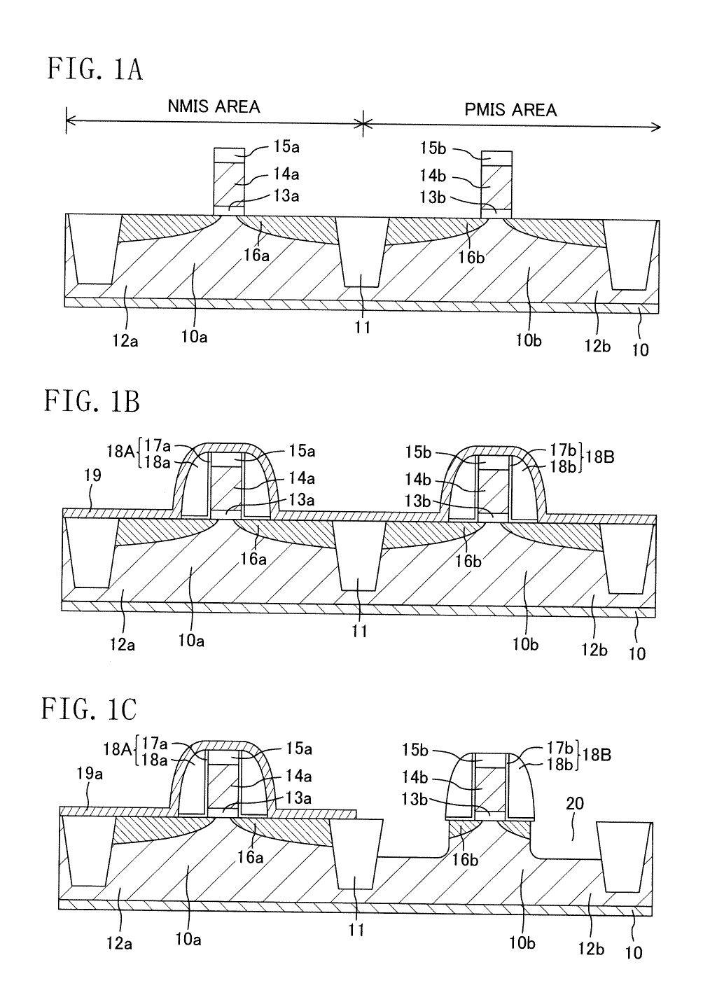

A semiconductor device of an embodiment of the present disclosure and a method for manufacturing the same will be described hereinafter with reference to FIGS. 1A-1C, 2A-2C, 3A-3C and 4.

A method for manufacturing a semiconductor device of an embodiment of the present invention will be described with reference to FIGS. 1A-3C. FIGS. 1A-3C are cross-sectional views, taken in the gate length direction, illustrating main steps of the method for manufacturing the semiconductor device of the embodiment of the present disclosure in the order in which the semiconductor device is manufactured. In FIGS. 1A-3C, an “NMIS area” is shown on the left and a “PMIS area” is shown on the right, as is viewed from the figures. The “NMIS area” as used herein refers to an area in which an n-type MIS transistor is formed, and the “PMIS area” as used herein refers to an area in which a p-type MIS transistor is formed. Note that, for simplicity of illustration, the NMIS area and the PMIS area are shown as if they are adjacent to each other.

First, as shown in FIG. 1A, an isolation region 11 that is a silicon oxide film, for example, embedded in a trench is formed in an upper portion of a semiconductor substrate 10 made of silicon, for example, by shallow trench isolation (STI), for example. This results in formation of a first semiconductor region 10a surrounded by the isolation region 11 in the semiconductor substrate 10 in the NMIS area and formation of a second semiconductor region 10b surrounded by the isolation region 11 in the semiconductor substrate 10 in the PMIS area. Thereafter, p-type impurity ions such as boron (B), for example, are implanted into the semiconductor substrate 10 in the NMIS area, and n-type impurity ions such as phosphorus (P), for example, are implanted into the semiconductor substrate 10 in the PMIS area, by ion implantation. The resultant semiconductor substrate 10 is subjected to thermal treatment to form a p-type well region 12a in the semiconductor substrate 10 in the NMIS area and an n-type well region 12b in the semiconductor substrate 10 in the PMIS area.

Thereafter, on the semiconductor substrate 10, formed sequentially are a gate insulating film formation film made of a silicon oxide film having a thickness of 2 nm, a gate electrode formation film made of a polysilicon film having a thickness of 90 nm, and a cap film formation film made of a silicon oxide film having a thickness of 20 nm. A resist (not shown) having a gate electrode shape is then formed on the cap film formation film by lithography. Using the resist as a mask, the cap film formation film, the gate electrode formation film, and the gate insulating film formation film are sequentially patterned by dry etching, whereby a first gate insulating film 13a, a first gate electrode 14a, and a first cap film 15a are sequentially formed on the first semiconductor region 10a, and also a second gate insulating film 13b, a second gate electrode 14b, and a second cap film 15b are sequentially formed on the second semiconductor region 10b. The resist is then removed. The first gate electrode 14a is an n-type gate electrode doped with an n-type impurity, and the second gate electrode 14b is a p-type gate electrode doped with a p-type impurity. The n-type first gate electrode 14a and the p-type second gate electrode 14b are formed in the following manner. After formation of the gate electrode formation film and before formation of the cap film formation film, an n-type impurity is implanted into the gate electrode formation film in the NMIS area, and a p-type impurity is implanted into the gate electrode formation film in the PMIS area. Thereafter, as described above, the cap film formation film is formed, and the cap film formation film, the gate electrode formation film, and the gate insulating film formation film are sequentially patterned, whereby the n-type first gate electrode 14a and the p-type second gate electrode 14b are formed.

Thereafter, n-type impurity ions such as arsenic (As), for example, are implanted into the first semiconductor region 10a by ion implantation using the first cap film 15a, the first gate electrode 14a, and the first gate insulating film 13a as a mask. By this ion implantation, n-type extension doped regions 16a comparatively shallow in junction depth are formed in a self-aligned manner in the first semiconductor region 10a to lie on opposite sides of the first gate electrode 14a. During this ion implantation, no n-type impurity ions are implanted into the first gate electrode 14a because the top surface of the first gate electrode 14a is covered with the first cap film 15a. Meanwhile, p-type impurity ions such as BF₂, for example, are implanted into the second semiconductor region 10b by ion implantation using the second cap film 15b, the second gate electrode 14b, and the second gate insulating film 13b as a mask. By this ion implantation, p-type extension doped regions 16b comparatively shallow in junction depth are formed in a self-aligned manner in the second semiconductor region 10b to lie on opposite sides of the second gate electrode 14b. During this ion implantation, no p-type impurity ions are implanted into the second gate electrode 14b because the top surface of the second gate electrode 14b is covered with the second cap film 15b.

As shown in FIG. 1B, a silicon oxide film having a thickness of 10 nm and a silicon nitride film having a thickness of 30 nm, for example, are sequentially formed on the entire surface of the semiconductor substrate 10, and then sequentially subjected to anisotropic etching. As a result, first and second sidewalls 18A and 18B, respectively including first and second inner sidewalls 17a and 17b made of the silicon oxide film having an L-shaped cross-section and first and second outer sidewalls 18a and 18b made of the silicon nitride film, are formed on the side surfaces of the first and second gate insulating films 13a and 13b, the first and second gate electrodes 14a and 14b, and the first and second cap films 15a and 15b.

Thereafter, a protection film 19 made of a silicon oxide film having a thickness of 10 nm, for example, is formed on the entire surface of the semiconductor substrate 10.

As shown in FIG. 1C, after a resist (not shown) covering the NMIS area while exposing the PMIS area is formed on the protection film 19 by lithography, the portion of the protection film 19 formed in the PMIS area is removed by wet etching using the resist as a mask, leaving a protection film 19a in the NMIS area. The resist is then removed.

Thereafter, regions in the second semiconductor region 10b lying laterally outside the second sidewalls 18B are etched by dry etching, to form recesses 20.

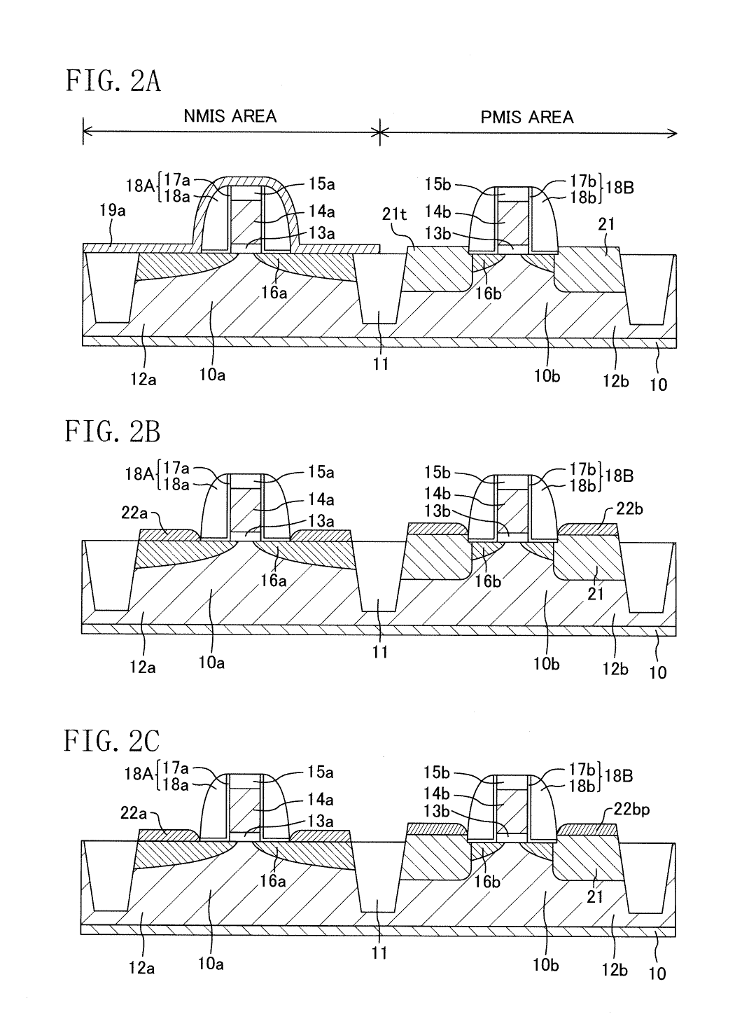

As shown in FIG. 2A, after removing natural oxide films (not shown), etc. formed inside the recesses 20, silane gas (SiH₄) and germane gas (GeH₄) are fed, together with a p-type impurity gas such as diborane gas (B₂H₆), at 650° C. to 700° C., for example, by epitaxial growth. By this growth, p-type germanium-containing silicon regions 21 having a germanium concentration of 30%, for example, (preferably in the range of 15% to 50%) are deposited in the recesses 20 and over the recesses 20 until the top surfaces thereof reach a level higher than the top surface of a region in the second semiconductor region 10b lying under the second gate insulating film 13b. During this deposition, no p-type germanium-containing silicon is deposited on regions in the first semiconductor region 10a lying laterally outside the first sidewalls 18A because the top surfaces of such regions are covered with the protection film 19a. Likewise, no p-type germanium-containing silicon is deposited on the first and second gate electrodes 14a and 14b because the top surface of the first gate electrode 14a is covered with the first cap film 15a and the protection film 19a, and the top surface of the second gate electrode 14b is covered with the second cap film 15b.

Thus, the p-type germanium-containing silicon regions 21 are formed laterally outside the second sidewalls 18B. Since the epitaxial growth is performed while feeding of a p-type impurity gas, p-conductivity type germanium-containing silicon regions are formed. In other words, the germanium-containing silicon regions are formed in regions in which a p-type impurity gas has been implanted (i.e., p-type impurity-doped regions). Also, since the p-type germanium-containing silicon regions 21 are deposited up to a level higher than the top surface of the region in the second semiconductor region 10b lying under the second gate insulating film 13b, the p-type germanium-containing silicon regions 21 have their thickened portions (21t in FIG. 2A) protruding from the level of the top surface of the region in the second semiconductor region 10b lying under the second gate insulating film 13b.

As shown in FIG. 2B, after removing the protection film 19a by wet etching, first silicon layers 22a having a thickness of 20 nm, for example, are deposited, by epitaxial growth, on regions in the first semiconductor region 10a lying laterally outside the first sidewalls 18A. Meanwhile, second silicon layers 22b having a thickness of 20 nm, for example, are deposited on the p-type germanium-containing silicon regions 21. During this deposition, germanium (Ge) in the p-type germanium-containing silicon regions 21 is diffused into the second silicon layers 22b from the bottom surfaces (i.e., the surfaces in contact with the p-type germanium-containing silicon regions 21) toward the top surfaces by thermal treatment in the epitaxial growth. Therefore, the germanium amount diffused into the second silicon layers 22b decreases with increase in the distance from the bottom surfaces, and thus the germanium concentration in the second silicon layers 22b is lower as the distance from the bottom surfaces is larger (the germanium concentration will be 0% in top surface portions of the second silicon layers 22b because it is unlikely for germanium to reach the top surface portions of the second silicon layers 22b).

Thus, the first silicon layers 22a are formed on the regions in the first semiconductor region 10a lying laterally outside the first sidewalls 18A, and the second silicon layers 22b in which the germanium concentration decreases with increase in the distance from the bottom surfaces are formed on the p-type germanium-containing silicon regions 21. Since this epitaxial growth is performed without involving feeding of an n-type or p-type impurity gas, the non-doped first and second silicon layers 22a and 22b are formed.

As shown in FIG. 2C, after a resist (not shown) covering the NMIS area while exposing the PMIS area is formed on the semiconductor substrate 10 by lithography, p-type impurity ions such as boron ions, for example, are implanted into the second silicon layers 22b by ion implantation under the conditions of an implantation energy of 2 keV and an implantation dose of 3×10¹⁵/cm², for example As a result, p-type second silicon layers 22bp that are the second silicon layers 22b doped with p-type impurity ions are formed. During this ion implantation, no p-type impurity ions are implanted into the second gate electrode 14b because the top surface thereof is covered with the second cap film 15b. The resist is then removed.

Naturally, since the germanium concentration in the second silicon layers 22b decreases with increase in the distance from the bottom surfaces (it is 0% in top surface portions of the second silicon layers 22b) as described above, the germanium concentration in the p-type second silicon layers 22bp also decreases with increase in the distance from the bottom surfaces (it is 0% in top surface portions of the p-type second silicon layers 22bp).

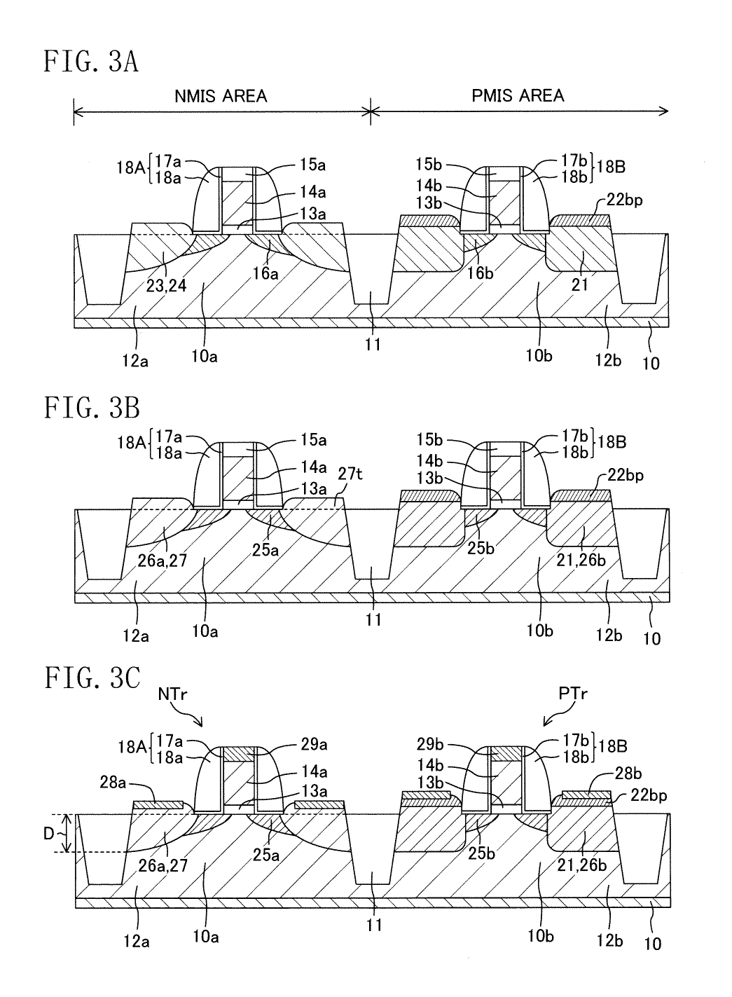

As shown in FIG. 3A, after a resist (not shown) covering the PMIS area while exposing the NMIS area is formed on the semiconductor substrate 10 by lithography, n-type impurity ions such as As ions, for example, are implanted into the first silicon layers 22a and the first semiconductor region 10a by ion implantation under the conditions of an implantation energy of 10 keV and an implantation dose of 2.5×10¹⁵/cm², for example, using the first sidewalls 18A as a mask. As a result, n-type source/drain doped regions 23 comparatively deep in junction depth are formed in a self-aligned manner in the first silicon layers 22a and regions in the first semiconductor region 10a lying under the first silicon layers 22a (i.e., regions in the first semiconductor region 10a lying laterally outside the first sidewalls 18A). During this ion implantation, no n-type impurity ions are implanted into the first gate electrode 14a because the top surface thereof is covered with the first cap film 15a. With this ion implantation of n-type impurity ions into the first silicon layers 22a and the first semiconductor region 10a, at least upper portions of the n-type source/drain doped regions 23 are amorphized. In this way, the n-type source/drain doped regions 23 are formed laterally outside the first sidewalls 18A.

Thereafter, carbon-containing ions such as C₁₆H₁₀ ions, for example, are implanted into the first silicon layers 22a and the first semiconductor region 10a by ion implantation under the conditions of an implantation energy of 2 keV and an implantation dose of 2.5×10¹⁵/cm², for example, using the first sidewalls 18A as a mask. As a result, carbon ion-doped regions 24 are formed in the first silicon layers 22a and regions in the first semiconductor region 10a lying under the first silicon layers 22a (i.e., regions in the first semiconductor region 10a lying laterally outside the first sidewalls 18A). During this ion implantation, no carbon-containing ions are implanted into the first gate electrode 14a because the top surface thereof is covered with the first cap film 15a. The resist is then removed.

Thus, the carbon ion-doped regions 24 are formed laterally outside the first sidewalls 18A. Since the carbon ion-doped regions 24 are formed in regions in the first semiconductor region 10a lying under the first silicon layers 22a and in the first silicon layers 22a, the top surfaces of the carbon ion-doped regions 24 are at a level higher than the top surface of a region in the first semiconductor region 10a lying under the first gate insulating film 13a by the thickness of the first silicon layers (22a in FIGS. 2B and 2C). Note that, in FIG. 3A, as well as FIGS. 3B and 3C to follow, the bottom surfaces of the first silicon layers are shown by the dotted lines although the first silicon layers no more exist in these steps.

When the same ions are implanted into an amorphous region and a crystalline region under the same ion implantation conditions, the amorphous region is more resistant to the ion implantation than the crystalline region. Therefore, an ion-doped region formed in the amorphous region can be made shallower than an ion-doped region formed in the crystalline region. Also, in general, carbon-containing molecular ions are heavier than carbon ions (C ions). Therefore, when carbon-containing molecular ions and carbon ions are individually implanted into the same region under the same ion implantation conditions, a region doped with carbon-containing molecular ions can be made shallower than a region doped with carbon ions. Thus, in this embodiment, after the formation of the n-type source/drain doped regions 23 of which at least upper portions are amorphized by implantation of n-type impurity ions, carbon-containing molecular ions (specifically, C₁₆H₁₀ ions, for example), used as the carbon-containing ions, are implanted to form the carbon ion-doped regions 24. By this way of implantation, the implantation depth of the carbon ion-doped regions 24 can be effectively prevented from exceeding the implantation depth of the n-type source/drain doped regions 23.

As shown in FIG. 3B, thermal treatment is performed at 650° C. for one minute, for example, whereby the n-type impurity contained in the n-type extension doped regions 16a is activated, forming n-type extension regions 25a, and also the p-type impurity contained in the p-type extension doped regions 16b is activated, forming p-type extension regions 25b. In this way, the n-type and p-type extension regions 25a and 25b are respectively formed in the first and second semiconductor regions 10a and 10b to lie on opposite sides of the first and second gate electrodes 14a and 14b.

By the thermal treatment, also, the n-type impurity contained in the n-type source/drain doped regions 23 is activated, forming n-type source/drain regions 26a, and the p-type impurity contained in the p-type germanium-containing silicon regions 21 is activated, forming p-type impurity-diffused regions 26b. In this way, the n-type source/drain regions (n-type impurity-diffused regions) 26a are formed laterally outside the first sidewalls 18A, and the p-type impurity-diffused regions 26b are formed laterally outside the second sidewalls 18B.

Moreover, by the thermal treatment, the carbon ion-doped regions 24 are crystallized, forming carbon-containing silicon regions 27 having a carbon concentration of 1%, for example (preferably in the range of 0.5% to 5%). In this way, the carbon-containing silicon regions 27 are formed laterally outside the first sidewalls 18A.

The carbon-containing silicon regions 27 are formed in the n-type source/drain regions (n-type impurity-diffused regions) 26a, and the germanium-containing silicon regions 21 are formed in the p-type impurity-diffused regions 26b. Also, as described above, the top surfaces of the carbon ion-doped regions 24 are at a level higher than the top surface of the region in the first semiconductor region 10a lying under the first gate insulating film 13a by the thickness of the first silicon layers (22a in FIGS. 2B and 2C). Therefore, the top surfaces of the carbon-containing silicon regions 27 are also at a level higher than the top surface of the region in the first semiconductor region 10a lying under the first gate insulating film 13a. Thus, the carbon-containing silicon regions 27 have their thickened portions (27t in FIG. 3B) protruding from the level of the top surface of the region in the first semiconductor region 10a lying under the first gate insulating film 13a.

As shown in FIG. 3C, the first and second cap films 15a and 15b are removed, exposing the top surfaces of the first and second gate electrodes 14a and 14b. Thereafter, natural oxide films (not shown), etc. formed on the top surfaces of the carbon-containing silicon regions 27 (n-type source/drain regions 26a), natural oxide films (not shown), etc. formed on the top surfaces of the p-type second silicon layers 22bp, and natural oxide films (not shown), etc. formed on the top surfaces of the first and second gate electrodes 14a and 14b are removed. A metal film for silicification (not shown) made of nickel (Ni) having a thickness of 11 nm, for example, is then deposited on the entire surface of the semiconductor substrate 10 by sputtering. First rapid thermal annealing (RTA) is then performed to allow silicon (Si) in the carbon-containing silicon regions 27, Si in the p-type second silicon layers 22bp, and Si in the first and second gate electrodes 14a and 14b to react with Ni in the metal film for silicification. As a result, first silicide layers 28a made of nickel silicide (or carbon-containing nickel silicide) having a thickness of 15 nm are formed on the carbon-containing silicon regions 27, and second silicide layers 28b made of nickel silicide having a thickness of 15 nm are formed on the p-type second silicon layers 22bp. Also, third and fourth silicide layers 29a and 29b made of nickel silicide having a thickness of 15 nm are respectively formed on the first and second gate electrodes 14a and 14b.

Since the germanium concentration in the p-type second silicon layers 22bp before the formation of the second silicide layers 28b decreases with increase in the distance from the bottom surface (it is 0% in top surface portions) as described above, no germanium is contained in the top surface portions of the p-type second silicon layers 22bp. Therefore, since only Si contained in portions of the p-type second silicon layers 22bp coming into contact with the metal film for silicification (i.e., the top surface portions of the p-type second silicon layers 22bp) reacts with Ni contained in the metal film for silicification, the second silicide layers 28b formed on the p-type second silicon layers 22bp are made of germanium-free nickel silicide. Also, since the germanium concentration in the p-type second silicon layers 22bp before the formation of the second silicide layers 28b decreases with increase in the distance from the bottom surface as described above, the germanium concentration in the p-type second silicon layers 22bp after the formation of the second silicide layers 28b also decreases with increase in the distance from the bottom surface. Therefore, upper portions of the p-type second silicon layers 22bp after the formation of the second silicide layers 28b are lower in germanium concentration than lower portions thereof, and at least the upper portions of the p-type second silicon layers 22bp are lower in germanium concentration than the p-type germanium-containing silicon regions 21. The p-type second silicon layer 22bp after the formation of the second silicide layer 28b (see FIG. 3C) refers to the portion of the p-type second silicon layer 22bp before the formation of the second silicide layer 28b (see FIGS. 2C-3B) excluding a portion thereof reacting with the metal film for silicification.

Thereafter, unreacted residues of the metal film for silicification left on the isolation region 11, the first and second sidewalls 18A and 18B, etc. are removed by immersion into an etchant. Second RTA is then performed at a temperature higher than the temperature used in the first RTA, to stabilize the silicide composition ratio of the first, second, third, and fourth silicide layers 28a, 28b, 29a, and 29b.

Subsequently, although not shown, an interlayer insulating film is formed on the entire surface of the semiconductor substrate 10, and then contact plugs connected to the first and second silicide layers 28a and 28b are formed through the interlayer insulating film. Thereafter, interconnects connected to the contact plugs are formed on the interlayer insulating film.

Thus, the semiconductor device of this embodiment can be manufactured.

Next, the configuration of the semiconductor device of the embodiment of the present disclosure will be described with reference to FIG. 3C.

As shown in FIG. 3C, the semiconductor device of this embodiment includes an n-type MIS transistor NTr formed on the semiconductor substrate 10 in the NMIS area and a p-type MIS transistor PTr formed on the semiconductor substrate 10 in the PMIS area.

The n-type transistor NTr includes: the first gate insulating film 13a formed on the first semiconductor region 10a; the first gate electrode 14a formed on the first gate insulating film 13a; the n-type extension regions 25a formed in the first semiconductor region 10a to lie on opposite sides of the first gate electrode 14a; the first sidewalls 18A formed on the side surfaces of the first gate electrode 14a; the n-type source/drain regions 26a formed laterally outside the first sidewalls 18A; the carbon-containing silicon regions 27 formed laterally outside the first sidewalls 18A; the first silicide layers 28a formed on the carbon-containing silicon regions 27 (n-type source-drain regions 26a); and the third silicide layer 29a formed on the first gate electrode 14a.

Likewise, the p-type transistor PTr includes: the second gate insulating film 13b formed on the second semiconductor region 10b; the second gate electrode 14b formed on the second gate insulating film 13b; the p-type extension regions 25b formed in the second semiconductor region 10b to lie on opposite sides of the second gate electrode 14b; the second sidewalls 18B formed on the side surfaces of the second gate electrode 14b; the p-type germanium-containing silicon regions 21 formed laterally outside the second sidewalls 18B; the p-type impurity-diffused regions 26b formed laterally outside the second sidewalls 18B; the p-type second silicon layers 22bp formed on the p-type germanium-containing silicon regions 21; the second silicide layers 28b formed on the p-type second silicon layers 22bp; and the fourth silicide layer 29b formed on the second gate electrode 14b.

The top surfaces of the carbon-containing silicon regions 27 are at a level higher than the top surface of the region in the first semiconductor region 10a lying under the first gate insulating film 13a as shown in FIG. 3C. The carbon-containing silicon regions 27 are formed in the regions in the first semiconductor region 10a lying laterally outside the first sidewalls 18A and in the first silicon layers (see the dotted lines in FIG. 3C). Also, the n-type source/drain regions (n-type impurity-diffused regions) 26a are formed in the carbon-containing silicon regions 27 as shown in FIG. 3C.

At least upper portions of the p-type second silicon layers 22bp are lower in germanium concentration than the p-type germanium-containing silicon regions 21.

The top surfaces of the germanium-containing silicon regions 21 are at a level higher than the top surface of the region in the second semiconductor region 10b lying under the second gate insulating film 13b as shown in FIG. 3C. The p-type impurity-diffused regions 26b are formed in the germanium-containing silicon regions 21.

The first and second sidewalls 18A and 18B respectively include: the first and second inner sidewalls 17a and 17b having an L-shaped cross-section formed on the side surfaces of the first and second gate electrodes 14a and 14b; and the first and second outer sidewalls 18a and 18b formed on the first and second inner sidewalls 17a and 17b.

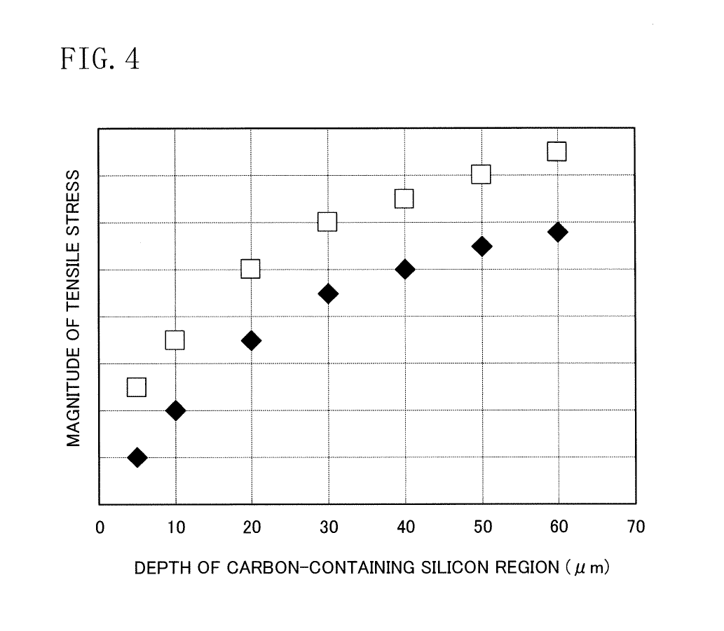

In order to describe the advantages of this embodiment in an effective way, the semiconductor device of this embodiment will be compared to the conventional semiconductor device. FIG. 4 is a graph showing the relationship between the depth of the carbon-containing silicon region and the magnitude of the tensile stress applied to the channel region in the gate length direction in the semiconductor device of this embodiment and in the conventional semiconductor device.

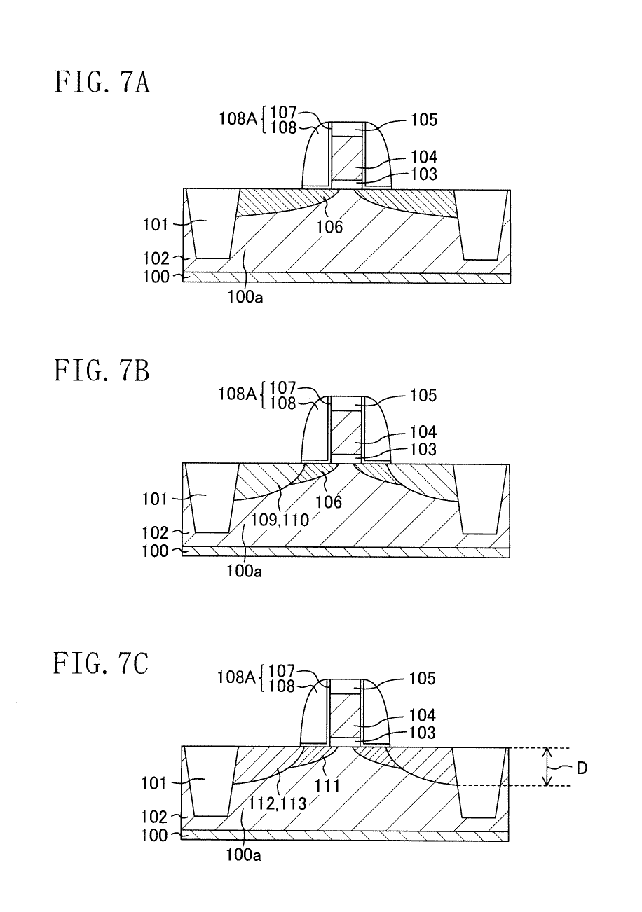

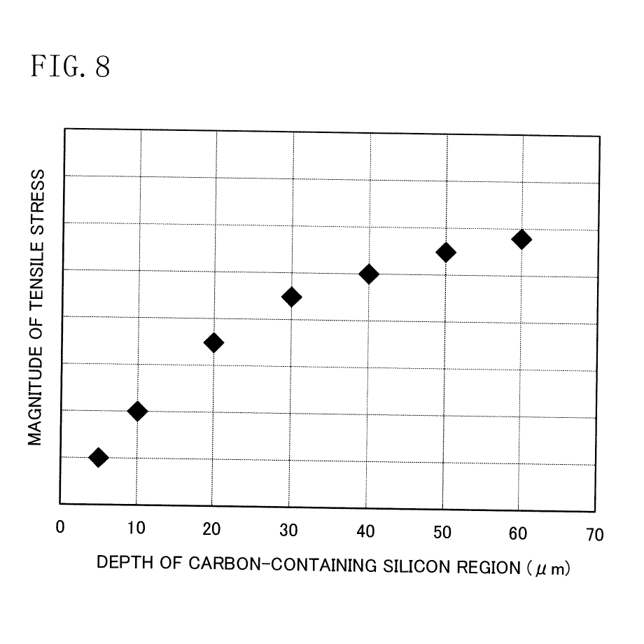

The x-axis in FIG. 4 represents the depth of the carbon-containing silicon region. As used in this embodiment, the “depth of the carbon-containing silicon region” refers to the depth from the top surface of the region in the first semiconductor region 10a lying under the first gate insulating film 13a to the deepest position of the bottom surface of the carbon-containing silicon region 27 (D in FIG. 3C, for example), as measured when the depth of the top surface of the region in the first semiconductor region 10a lying under the first gate insulating film 13a is assumed as the reference depth (i.e., 0 nm). As used in the conventional case, the “depth of the carbon-containing silicon region” refers to the depth from the top surface of the region in the semiconductor region 100a lying under the gate insulating film 103 to the deepest position of the bottom surface of the carbon-containing silicon region 113 (D in FIG. 7C, for example), as measured when the depth of the top surface of the region in the semiconductor region 100a lying under the gate insulating film 103 is assumed as the reference depth (i.e., 0

The y-axis in FIG. 4 represents, in this embodiment, the magnitude of the tensile stress applied to the channel region in the gate length direction by the carbon-containing silicon region 27 having the thickened portion 27t and having a depth of X (X=5, 10, 20, 30, 40, 50, and 60) nm. In the conventional case, the y-axis represents the magnitude of the tensile stress applied to the channel region in the gate length direction by the carbon-containing silicon region 113 having a depth of X (X=5, 10, 20, 30, 40, 50, and 60) nm.

In FIG. 4, symbol □ represents the semiconductor device of this embodiment and symbol represents the conventional semiconductor device.

Differences in configuration between the semiconductor device of this embodiment and the conventional semiconductor device will be described hereinafter.

In this embodiment, as shown in FIG. 3C, the carbon-containing silicon regions 27 are formed in the regions in the first semiconductor region 10a lying under the first silicon layers (see the dotted lines in FIG. 3C) (i.e., the regions in the first semiconductor region 10a lying laterally outside the first sidewall 18A) and in the first silicon layer. Therefore, the top surfaces of the carbon-containing silicon regions 27 are at a level higher than the top surface of the region in the first semiconductor region 10a lying under the first gate insulating film 13a, and thus the carbon-containing silicon regions 27 have their thickened portions (27t in FIG. 3B) protruding from the level of the top surface of the region in the first semiconductor region 10a lying under the first gate insulating film 13a.

Conventionally, however, as shown in FIG. 7C, the carbon-containing silicon regions 113 are formed in only the regions in the semiconductor region 100a lying laterally outside the sidewalls 108A. Therefore, the top surfaces of the carbon-containing silicon regions 113 are at the same level as the top surface of the region in the semiconductor region 100a lying under the gate insulating film 103. Thus, the carbon-containing silicon regions 113, which are not formed above the level of the top surface of the region in the semiconductor region 100a lying under the gate insulating film 103, have no such a thickened portion as that in this embodiment.

Therefore, even though the depth of the carbon-containing silicon regions in this embodiment is the same as that of the conventional carbon-containing silicon regions, the top surfaces of the carbon-containing silicon regions in this embodiment are at a level higher than the top surfaces of the conventional carbon-containing silicon regions, with the thickened portions formed in the carbon-containing silicon regions in this embodiment. Thus, as shown in FIG. 4, the magnitude of the tensile stress in this embodiment can be increased compared to the conventionally-obtained magnitude by the magnitude of the tensile stress applied by the thickened portions.

In this embodiment, the top surfaces of the carbon-containing silicon regions 27 are at a level higher than the top surface of the region in the first semiconductor region 10a lying under the first gate insulating film 13a, and thus the carbon-containing silicon regions 27 have their thickened portions 27t protruding from the level of the top surface of the region in the first semiconductor region 10a lying under the first gate insulating film 13a. Therefore, since the thickened portions 27t can effectively apply a tensile stress to the channel region in the first semiconductor region 10a in the gate length direction, the magnitude of the tensile stress applied to the channel region in the first semiconductor region 10a in the gate length direction can be increased effectively. Thus, the drive capability of the n-type MIS transistor can be further improved.

Likewise, the top surfaces of the p-type germanium-containing silicon regions 21 are at a level higher than the top surface of the region in the second semiconductor region 10b lying under the second gate insulating film 13b, and thus the p-type germanium-containing silicon regions 21 have their thickened portions 21t protruding from the level of the top surface of the region in the second semiconductor region 10b lying under the second gate insulating film 13b. Therefore, since the thickened portions 21t can effectively apply a compressive stress to the channel region in the second semiconductor region 10b in the gate length direction, the magnitude of the compressive stress applied to the channel region in the second semiconductor region 10b in the gate length direction can be increased effectively. Thus, the drive capability of the p-type MIS transistor can be further improved.

In addition, since no germanium is contained in the top surface portions of the p-type second silicon layers 22bp at the time before the formation of the second silicide layers 28b (i.e., the portions of the p-type second silicon layers 22bp coming into contact with the metal film for silicification), the second silicide layers 28b formed on the p-type second silicon layers 22bp are free of germanium. Thus, the heat resistance of the second silicide layers 28b can be ensured.

Unlike the above case, carbon is contained in the carbon-containing silicon regions 27 at the time before the formation of the first silicide layers 28a, and thus the first silicide layers 28a formed on the carbon-containing silicon regions 27 may possibly contain carbon.

However, since a silicide layer containing carbon is not poor in heat resistance, unlike a silicide layer containing germanium, the heat resistance of the first silicide layers 28a can be ensured even if carbon is contained in the first silicide layers 28a.

Moreover, in this embodiment, as shown in FIG. 3A, after the formation of the n-type source/drain doped regions 23 of which at least upper portions have been amorphized by implantation of n-type impurity ions, carbon-containing molecular ions (specifically, C₁₆H₁₀ ions, for example), used as the carbon-containing ions, are implanted to form the carbon ion-doped regions 24. By this way of implantation, the implantation depth of the carbon ion-doped regions 24 can be effectively prevented from exceeding the implantation depth of the n-type source/drain doped regions 23. Therefore, as shown in FIG. 3B, it is possible to prevent occurrence of junction leakage, which may occur when the depth of the carbon-containing silicon regions 27 exceeds the depth of the n-type source/drain regions 26a.

In this embodiment, described as a specific example is the case that the implantation depth of the carbon ion-doped regions 24 is the same as the implantation depth of the n-type source/drain doped regions 23 as shown in FIG. 3A, and the depth of the carbon-containing silicon regions 27 is the same as the depth of the n-type source/drain regions 26a as shown in FIG. 3B. The present disclosure is not limited to this. For example, the implantation depth of the carbon ion-doped regions may be made shallower than the implantation depth of the n-type source/drain doped regions, and the depth of the carbon-containing silicon regions may be made shallower than the depth of the n-type source/drain regions.

Also, in this embodiment, described as a specific example is the case that, for the purpose of effectively preventing the implantation depth of the carbon ion-doped regions 24 from exceeding the implantation depth of the n-type source/drain doped regions 23, the n-type source/drain doped regions 23 of which at least upper portions have been amorphized are first formed by implantation of n-type impurity ions, and then the carbon ion-doped regions 24 are formed by implantation of carbon-containing molecular ions used as the carbon-containing ions, as shown in FIG. 3A. The present disclosure is not limited to this.

For example, as the first alternative, the carbon ion-doped regions may be first formed by implanting carbon-containing molecular ions used as the carbon-containing ions, and then the n-type source/drain doped regions may be formed by implantation of n-type impurity ions.

As the second alternative, the n-type source/drain doped regions of which at least upper portions have been amorphized may be first formed by implantation of n-type impurity ions, and then the carbon ion-doped regions may be formed by implantation of carbon ions used as the carbon-containing ions.

Also, in this embodiment, described as a specific example is the case that the p-type germanium-containing silicon regions 21 are deposited in the recesses 20 and over the recesses 20 by epitaxial growth until the top surfaces thereof reach a level higher than the top surface of the region in the second semiconductor region 10b lying under the second gate insulating film 13b as shown in FIG. 2A. The present disclosure is not limited to this. For example, p-type germanium-containing silicon regions may be deposited in the recesses by epitaxial growth.

Also, in this embodiment, described as a specific example is the case that, after formation of the first and second silicon layers 22a and 22b as shown in FIG. 2B, the p-type second silicon layers 22bp are formed as shown in FIG. 2C, then the n-type source/drain doped regions 23 and the carbon ion-doped regions 24 are sequentially formed as shown in FIG. 3A, and thereafter thermal treatment is performed as shown in FIG. 3B. The present disclosure is not limited to this.

For example, after formation of the first and second silicon layers, the n-type source/drain doped regions and then the carbon ion-doped regions may be sequentially formed (or the carbon ion-doped regions and then the n-type source/drain doped regions may be sequentially formed) without formation of the p-type second silicon layers. Thereafter, after formation of the p-type second silicon layers, thermal treatment may be performed.

In other words, it is only necessary to perform, after the step of forming the first and second silicon layers and before the thermal treatment step, 1) the step of forming the p-type second silicon layers and 2) the step of sequentially forming the n-type source/drain doped regions and then the carbon ion-doped regions (or the step of sequentially forming the carbon ion-doped regions and then the n-type source/drain doped regions).

Also, in this embodiment, described as a specific example is the case that n-type and p-type impurity ions are respectively implanted into the first and second semiconductor regions 10a and 10b using the first and second gate electrodes 14a and 14b as a mask, to form the n-type and p-type extension doped regions 16a and 16b as shown in FIG. 1A, and then the first and second sidewalls 18A and 18B are respectively formed on the side surfaces of the first and second gate electrodes 14a and 14b. The present disclosure is not limited to this. For example, before formation of the n-type and p-type extension doped regions, first and second offset spacers may be formed on the side surfaces of the first and second gate electrodes. Using the first and second gate electrodes with the first and second offset spacers formed on the side surfaces thereof as a mask, n-type and p-type impurity ions may be implanted into the first and second semiconductor regions, to form the n-type and p-type extension doped regions. Thereafter, the first and second sidewalls may be formed on the side surfaces of the first and second gate electrodes via the first and second offset spacers.

<First Variation of Embodiment>

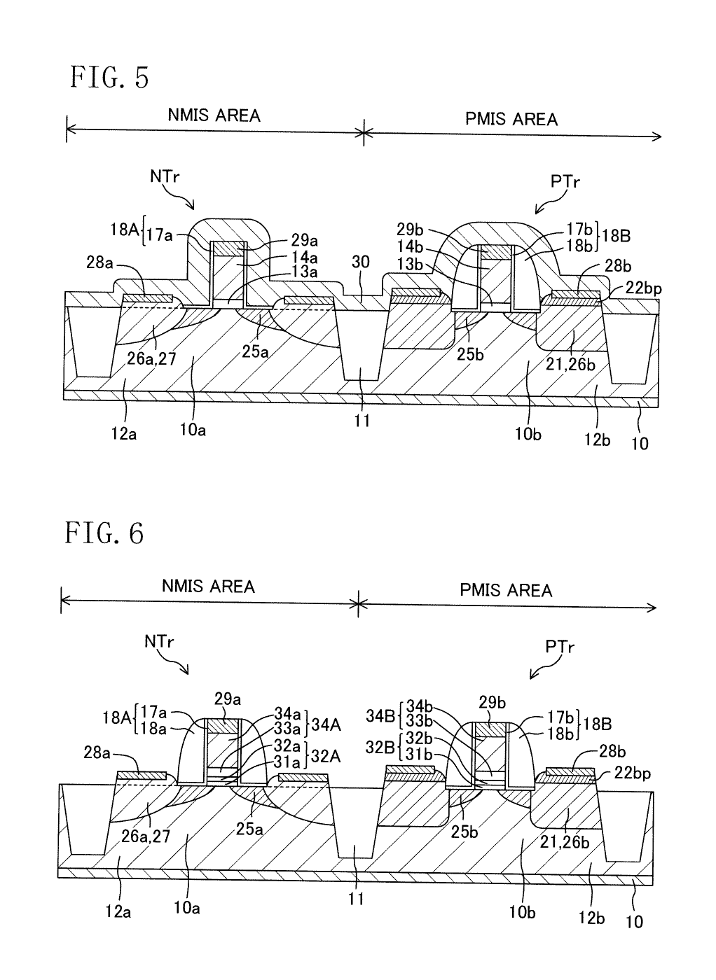

A semiconductor device of the first variation of the embodiment of the present disclosure will be described with reference to FIG. 5. FIG. 5 is a cross-sectional view illustrating a step of a method for manufacturing the semiconductor device of the first variation of the embodiment of the present disclosure. In FIG. 5, the same components as those in the above embodiment will be denoted by the same reference numerals as those in FIG. 3C. In this variation, therefore, description of such components that have already been described in the above embodiment is appropriately omitted.

Although illustration is omitted, the steps shown in FIGS. 1A-3C in the above embodiment are sequentially executed, to obtain the configuration shown in FIG. 3C.

Thereafter, as shown in FIG. 5, the first outer sidewalls 18a are removed to expose the first inner sidewalls 17a. Subsequently, a stress insulating film 30, which causes a tensile stress in the channel region in the first semiconductor region 10a in the gate length direction, is formed on the entire surface of the semiconductor substrate 10.

Thereafter, although illustration is omitted, an interlayer insulating film, contact plugs, interconnects, etc. are formed as in the above embodiment.

Thus, the semiconductor device of this variation can be manufactured. Differences in configuration between this variation and the above embodiment are as follows.

While the n-type MIS transistor NTr in this variation includes the first sidewalls 18A each comprised of the first inner sidewall 17a as shown in FIG. 5, the n-type MIS transistor NTr in the above embodiment includes the first sidewalls 18A each comprised of the first inner sidewall 17a and the first outer sidewall 18a as shown in FIG. 3C.

Also, the n-type MIS transistor NTr in this variation further includes the stress insulating film 30 that is formed above the first semiconductor region 10a to be in contact with the first inner sidewalls 17a and causes a tensile stress in the channel region in the first semiconductor region 10a in the gate length direction.

In this variation, advantages similar to those obtained in the above embodiment can be obtained.

In addition, since the stress insulating film 30 can cause a tensile stress in the channel region in the first semiconductor region 10a in the gate length direction, the drive capability of the n-type MIS transistor NTr can be further improved.

Moreover, with the formation of the stress insulating film 30 in contact with the first inner sidewalls 17a, not via the first outer sidewalls, the stress insulating film 30 can be closer to the channel region in the first semiconductor region 10a by the thickness of the first outer sidewalls removed. Therefore, the tensile stress caused by the stress insulating film 30 can be effectively applied to the channel region in the first semiconductor region 10a in the gate length direction.

Furthermore, with the formation of the stress insulating film 30 in contact with the first inner sidewalls 17a, not via the first outer sidewalls, the stress insulating film 30 can be thickened by the thickness of the first outer sidewalls removed. Therefore, the tensile stress caused by the stress insulating film 30 can be effectively applied to the channel region in the first semiconductor region 10a in the gate length direction.

In this variation, described as a specific example is the case that, for the purpose of effectively applying the tensile stress caused by the stress insulating film 30 to the channel region in the first semiconductor region 10a in the gate length direction, the stress insulating film 30 is formed in contact with the first inner sidewalls 17a after removal of the first outer sidewalls 18a. The present disclosure is not limited to this. For example, the stress insulating film may be formed without removing the first outer sidewalls 18a.

Also, in this variation, described as a specific example is the case that, for the purpose of further improving the drive capability of the n-type MIS transistor NTr, the stress insulating film 30 that causes a tensile stress in the channel region in the first semiconductor region 10a in the gate length direction, is formed above the first semiconductor region 10a. The present disclosure is not limited to this. For example, a stress insulating film that causes a compressive stress in the channel region in the second semiconductor region in the gate length direction may be formed above the second semiconductor region 10b. In this case, the drive capability of the p-type MIS transistor can be further improved.

<Second Variation of Embodiment>

A semiconductor device of the second variation of the embodiment of the present disclosure will be described with reference to FIG. 6. FIG. 6 is a cross-sectional view illustrating a configuration of the semiconductor device of the second variation of the embodiment of the present disclosure.

Differences in configuration between this variation and the above embodiment are as follows.

As shown in FIG. 6, the n-type MIS transistor NTr in this variation includes a first gate insulating film 32A formed on the first semiconductor region 10a and a first gate electrode 34A formed on the first gate insulating film 32A. The first gate insulating film 32A includes a first insulating film 31a made of a silicon oxide film, for example, and a first high-k insulating film 32a made of a lanthanum-containing hafnium insulating film, for example, formed on the first insulating film 31a. The first gate electrode 34A includes a first metal film 33a made of a tantalum nitride (TaN) film, for example, formed in contact with the first gate insulating film 32A and a first conductive film 34a made of a polysilicon film, for example, formed on the first metal film 33a.

In the above embodiment, however, as shown in FIG. 3C, the n-type MIS transistor NTr includes the first gate insulating film 13a made of a silicon oxide film, for example, formed on the first semiconductor region 10a and the first gate electrode 14a made of a polysilicon film, for example, formed on the first gate insulating film 13a.

Likewise, as shown in FIG. 6, the p-type MIS transistor PTr in this variation includes a second gate insulating film 32B formed on the second semiconductor region 10b and a second gate electrode 34B formed on the second gate insulating film 32B. The second gate insulating film 32B includes a second insulating film 31b made of a silicon oxide film, for example, and a second high-k insulating film 32b made of an aluminum-containing hafnium insulating film, for example, formed on the second insulating film 31b. The second gate electrode 34B includes a second metal film 33b made of a titanium nitride (TiN) film, for example, formed in contact with the second gate insulating film 32B and a second conductive film 34b made of a polysilicon film, for example, formed on the second metal film 33b.

In the above embodiment, however, as shown in FIG. 3C, the p-type MIS transistor PTr includes the second gate insulating film 13b made of a silicon oxide film, for example, formed on the second semiconductor region 10b and the second gate electrode 14b made of a polysilicon film, for example, formed on the second gate insulating film 13b.

In this variation, the case of using a TaN film as the first metal film 33a is described as a specific example. The present disclosure is not limited to this, but a TiN film, for example, may be used. Also, the case of using a TiN film as the second metal film 33b is described as a specific example. The present disclosure is not limited to this, but a TaN film, for example, may be used.

The present disclosure, in which the magnitude of the tensile stress applied to the channel region in the gate length direction can be effectively increased, is useful in a semiconductor device including an n-type MIS transistor having a carbon-containing silicon region and a method for manufacturing such a semiconductor device.

What is claimed is:

1. A semiconductor device comprising:
at least an n-type MIS transistor,
wherein
the n-type MIS transistor includes
a first gate insulating film formed on a first semiconductor region in a semiconductor substrate,
a first gate electrode formed on the first gate insulating film,
first sidewalls formed on side surfaces of the first gate electrode,
first silicon layers made of a first epitaxial layer found on regions in the first semiconductor region lying laterally outside the first sidewalls, and
carbon-containing silicon regions formed in the first silicon layers and in regions in an upper portion of the first semiconductor region lying immediately under the first silicon layers.

2. The semiconductor device of claim 1, wherein
the highest top surfaces of the carbon-containing silicon regions are at a level higher than the highest top surface of a region in the first semiconductor region lying immediately under the first gate insulating film.

3. The semiconductor device of claim 1, wherein
the maximum depth of portions of the carbon-containing silicon regions formed in the first semiconductor region is larger than the maximum thickness of the first silicon layers.

4. The semiconductor device of claim 1, wherein
the carbon-containing silicon regions include carbon implanted in the first silicon layers and in the regions in an upper portion of the first semiconductor region lying immediately under the first silicon layers.

5. The semiconductor device of claim 1, wherein
n-type impurity-diffused regions are formed in the carbon-containing silicon regions.

6. The semiconductor device of claim 1, wherein
each of the first sidewalls includes a first inner sidewall having an L-shaped cross-section formed on a side surface of the first gate electrode and a first outer sidewall formed on the first inner sidewall.

7. The semiconductor device of claim 1, further comprising:
a stress insulating film formed above the first semiconductor region, configured to cause a tensile stress in a channel region in the first semiconductor region in a gate length direction.

8. The semiconductor device of claim 7, wherein
each of the first sidewalls includes a first inner sidewall having an L-shaped cross-section formed on a side surface of the first gate electrode, and
the stress insulating film is formed in contact with an L-shaped surface of the first inner sidewall.

9. The semiconductor device of claim 1, further comprising:
first silicide layers formed on the carbon-containing silicon regions.

10. The semiconductor device of claim 9, wherein
the first gate electrode includes a first polysilicon film formed on the first gate insulating film, and
the semiconductor device further comprises a second silicide layer formed on the first polysilicon film.

11. The semiconductor device of claim 10, wherein
the first gate insulating film includes a first high-k insulating film, and
the first gate electrode includes a first metal film formed between the first gate insulating film and the first polysilicon film.

12. The semiconductor device of claim 2, wherein
the first gate electrode includes a first polysilicon film formed on the first gate insulating film,
the semiconductor device further comprises
first silicide layers formed on the carbon-containing silicon regions, and
a second silicide layer formed on the first polysilicon film, and
the maximum depth of portions of the carbon-containing silicon regions formed in the first semiconductor region is larger than the maximum thickness of the first silicon layers.

13. The semiconductor device of claim 1, wherein
the carbon concentration of the carbon-containing silicon regions is 0.5% or more.

14. The semiconductor device of claim 1, further comprising:
a p-type MIS transistor,
wherein
the p-type MIS transistor includes
a second gate insulating film formed on a second semiconductor region in the semiconductor substrate,
a second gate electrode formed on the second gate insulating film,
second sidewalls formed on side surfaces of the second gate electrode, and
germanium-containing silicon regions formed laterally outside the second sidewalls.

15. The semiconductor device of claim 14, wherein
the germanium-containing silicon regions are made of a second epitaxial layer formed in recesses formed by etching regions in the second semiconductor region located laterally outside the second sidewalls.

16. The semiconductor device of claim 14, further comprising:
second silicon layers made of the first epitaxial layer formed on the germanium-containing silicon regions.

17. The semiconductor device of claim 16, further comprising:
second silicide layers formed on the second silicon layers.

18. The semiconductor device of claim 16, wherein
the highest top surfaces of the second silicon layers are at a level higher than the highest top surfaces of the first silicon layers.

19. The semiconductor device of claim 14, wherein
the second gate insulating film includes a second high-k insulating film, and
the second gate electrode includes a second metal film formed in contact with the second gate insulating film.

20. The semiconductor device of claim 14, wherein
the germanium concentration of the germanium-containing silicon regions is 15% or more.
